(19) United States
(12) Patent Application Publication
(10) Pub. No.: US 2011/0139221 A1
(43) Pub. Date: Jun. 16, 2011

(54) PHOTOVOLTAIC SYSTEM

(75) Inventor: Johann Giritsch, Heilbronn (DE)

(73) Assignees: Johann GIRITSCH, Heilbronn (DE); Dorian MITTLER, Stuttgart (DE); Peter FÜRST, St. Pantaleon (CH); Jürgen TRITSCHLER, Elzach (DE)

(21) Appl. No.: 13/001,917

(22) PCT Filed: Jul. 1, 2009
(86) PCT No.: PCT/DE2009/000923

§ 371 Date: Mar. 2, 2011

(30) Foreign Application Priority Data
Jul. 2, 2008 (DE) 20 2008 008 747.3

(51) Int. Cl. H01L 31/058

(52) U.S. Cl. 136/248

(57) ABSTRACT

A photovoltaic system includes planar photovoltaic elements that generates electricity from solar irradiation and feed it into a power grid and/or a battery unit. A cooling coil that communicates with a first heat pump via a heat pump circuit is arranged under each photovoltaic element and feeds heat generated during operation of the photovoltaic element to the first heat pump, which communicates with a first carrier medium circuit containing a first carrier medium. A heat accumulator unit containing a heat accumulating medium is arranged in the first carrier medium circuit, the thermal energy of the first carrier medium being transferred to the heat accumulating medium within the heat accumulator unit. In addition, at least one other heat consumption circuit containing a second carrier medium communicates with the heat accumulator unit, and the thermal energy of the heat accumulating medium is transferred to the second carrier medium as needed.

### CROSS-REFERENCE TO RELATED PATENT APPLICATIONS

This application is a U.S. National Phase Application under 35 U.S.C. §371 of International Patent Application No. PCT/DE2009/000923, filed Jul. 1, 2009, and claims the benefit of German Patent Application No. 202008008747.3, filed Jul. 2, 2008, all of which are incorporated by reference herein. The International Application was published in German on Jan. 7, 2010 as International Publication No. WO 2010/000240 under PCT Article 21(2).

### FIELD OF THE INVENTION

The present invention relates to a photovoltaic system having planar photovoltaic elements, which when subjected to solar irradiation from above generate electrical energy which is fed into a power supply network and/or is supplied to an electricity storage unit.

### BACKGROUND OF THE INVENTION

The use of photovoltaic systems for converting the sun's energy into electrical energy is well known. The planar photovoltaic elements of such photovoltaic systems are mounted for example on roof surfaces which are aligned with the sun. Inverters which enable the electrical energy generated by the photovoltaic element to be fed into a power supply network are connected to the photovoltaic elements. A not inconsiderable amount of process heat is produced when photovoltaic elements are operating. As the inverters are only able to work up to a defined maximum temperature (for example 65°) these are switched off when the maximum temperature is exceeded in order to protect them against damage. The efficiency of the overall system suffers from this.

### SUMMARY OF THE INVENTION

Starting from the stated prior art, the present invention is based on the technical problem and object of improving the efficiency of a photovoltaic system of the kind mentioned in the introduction.

The photovoltaic system according to the invention is accordingly characterized in that a cooling unit is arranged below each photovoltaic element, a cooling unit which communicates with a first heat pump via a heat pump circuit is arranged below each voltaic element, wherein the cooling unit feeds the process heat generated during operation of the photovoltaic element to the first heat pump, the first heat pump communicates with a first carrier medium circuit containing a first carrier medium, a heat storage unit containing a heat storage medium is arranged in the first carrier medium circuit, the thermal energy of the first carrier medium being transferred to the heat storage medium within the heat storage unit, and at least one further heat consumption circuit containing a second carrier medium communicates with the heat storage unit, and the thermal energy of the heat storage medium is transferred to the second carrier medium of the further heat consumption circuit as required.

The basic concept of the present invention lies in dissipating the process heat generated during operation of the photovoltaic elements and utilizing the energy thereof. On the one hand, this has the effect that the efficiency of electricity generation by the photovoltaic elements is improved, as the switching off of the inverters as a result of exceeding the maximum operating temperature can substantially be avoided. Furthermore, this extracted process heat is fed to a heat storage unit which then in turn feeds the stored heat to different consumption circuits as required.

The first heat pump is used to achieve a temperature of 60° to 70° C. (Celsius) in the heat storage unit:

According to an advantageous embodiment, it is possible to arrange an insulating layer below the cooling unit in order to increase the efficiency.

Preferably, thermal energy is transferred from the first carrier medium to the storage carrier medium by means of a first heat exchanger. Likewise, the thermal energy can be transferred from the storage medium to the further heat consumption circuits within the heat store by means of a further second heat exchanger in each case.

To control the temperature relationships in the first carrier medium circuit, it is particularly advantageous to use a first circulating pump which is preferably fed and switched by a thermostat which is provided within the first carrier medium circuit and on the heat storage unit. The power of the circulating pump can be variably adjusted in an advantageous manner.

A circuit for room heating or for the provision of hot water is a possible example of a further heat consumption circuit.

Furthermore, the further heat consumption circuit can be fed to a heat pump, wherein, according to a particularly advantageous embodiment, a steam generation unit which communicates with a steam circuit is connected to the heat pump, and a steam turbine to which the generated steam is applied is arranged in the steam circuit.

The steam turbine can be connected to a generator for generating electricity, for example.

In an alternative advantageous embodiment, the steam turbine drives a nitrogen liquefaction unit which liquefies the nitrogen in the ambient air, a nitrogen storage unit being provided in which the liquid nitrogen produced is stored in such a way that it can be drawn off.

A particularly preferred embodiment of the system according to the invention is characterized in that the steam turbine can be switched in such a way that it is driven by the steam of the steam circuit or by nitrogen drawn from the nitrogen storage unit which is fed via an evaporator. As a result of this embodiment, at night or when no heat is being taken off elsewhere, it is possible for the steam turbine to be driven by the previously generated nitrogen, and electricity can therefore be fed into the supply network by means of the generator current without process heat being required from the photovoltaic elements and this process heat not being available.

Further embodiments and advantages of the invention can be seen from the characteristics additionally listed in the claims and from the exemplary embodiments indicated below. The characteristics of the claims can be combined with one another in any way in so far as they are not obviously mutually exclusive.

### BRIEF DESCRIPTION OF THE DRAWING

The invention and advantageous embodiments and improvements thereof are described and explained in more detail below with reference to the examples shown in the drawing. According to the invention, the characteristics to be seen from the description and the drawing can be applied individually in their own right or jointly in any combination. In the drawing:

FIG. 1 shows highly schematically a photovoltaic system having a first carrier medium circuit to which the process heat of the photovoltaic system is fed and which stores this process heat within a storage unit, at least one further heat consumption circuit being connected to the storage unit, and

FIG. 2 shows highly schematically a photovoltaic system according to FIG. 1, wherein a first heat pump is connected upstream of the first carrier medium circuit and in total three further heat consumption circuits for room heating, a heat pump and the provision of hot water are connected, the heat pump being connected to a steam generation unit, the steam of which is fed to a steam turbine.

### DETAILED DESCRIPTION OF THE INVENTION

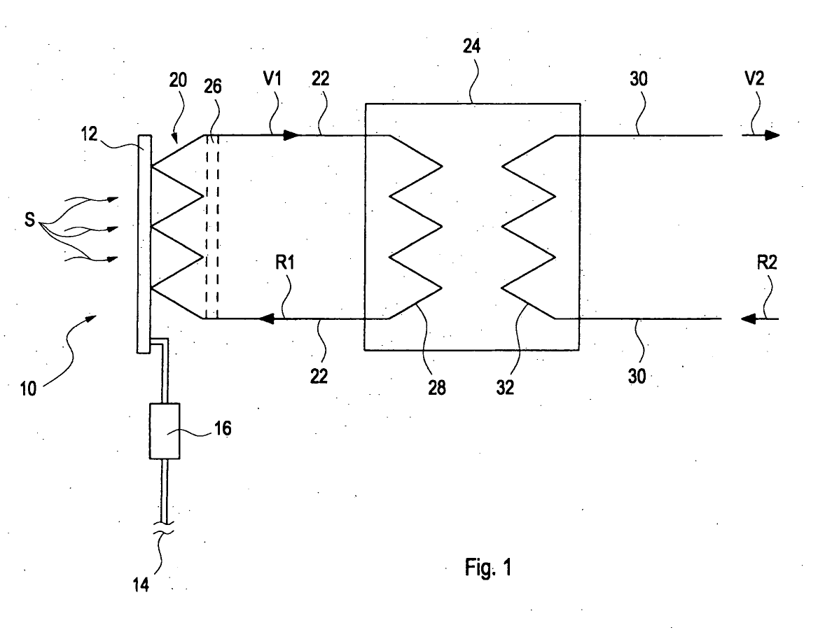

A photovoltaic system 10 having a photovoltaic element 12 shown by way of example which is subjected to solar irradiation S from above is depicted highly schematically in FIG. 1. The photovoltaic element 12 is wired to an inverter 16 which feeds the electrical energy generated by the photovoltaic element 12 into a power supply network which is shown symbolically in FIG. 1.

A cooling unit 20, which communicates with the first heat pump 36 via a heat pump circuit 34, is arranged on the underside of the photovoltaic element 12. Furthermore, the first heat pump 36, which is shown highly schematically in FIG. 1, is incorporated into a first carrier medium circuit 22 having a feed V1 and a return R1, the first carrier medium circuit 22 being routed partially within a heat storage unit 24 which is filled with a heat storage medium. The first heat pump 36 is used to achieve a temperature of approx. 60° to 70° C. (Celsius) in the heat storage unit 24.

The first carrier medium circuit 22 has a first heat exchanger 28 within the heat storage unit 24.

A further heat consumption circuit 30 with its feed V2 and its return R2 is connected schematically to the heat storage unit 24 in FIG. 1, the further heat consumption circuit 30 having a second heat exchanger 32 within the heat storage unit 24.

In operation, the photovoltaic system 10 works as follows. The process heat in the photovoltaic element 12 is transferred via the cooling unit 20 to the first carrier medium of the first carrier medium circuit 22. The heat energy of the first carrier medium is transferred to the heat storage medium via the first heat exchanger 28 within the heat storage unit 24.

The thermal energy of the heat storage medium of the heat storage unit 24 is transferred to the second storage medium of the further consumption circuit 30 as required by means of the second heat exchanger 32.

On the one hand, such a system uses the process heat of the photovoltaic element 12 and at the same time cools the photovoltaic element 12 so that a failure or switching off of the inverter 16 as a result of too high a temperature can substantially be avoided.

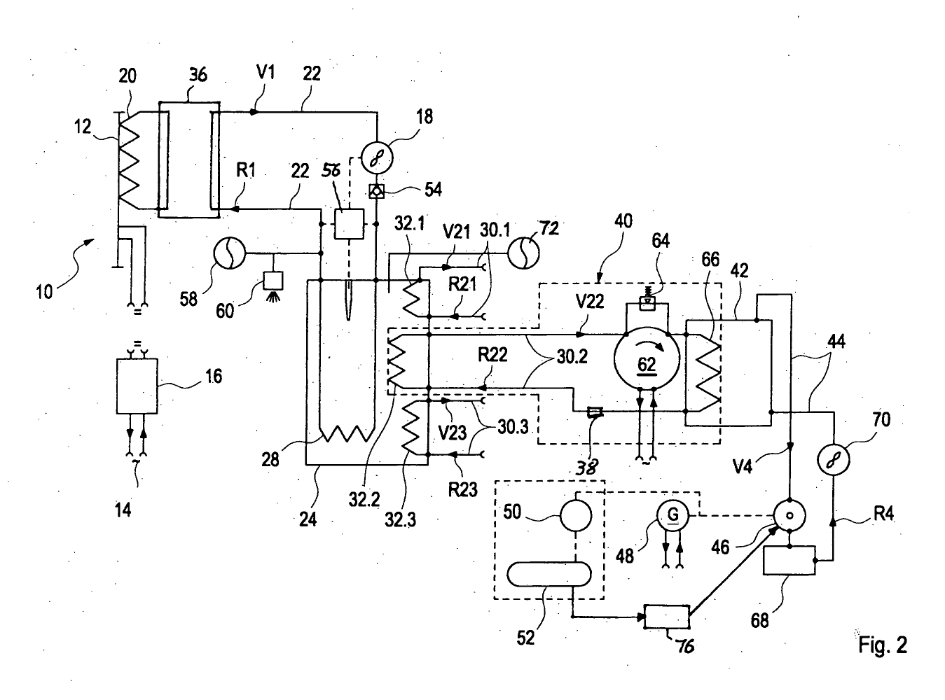

The photovoltaic system according to FIG. 1 is shown highly schematically with further details in FIG. 2, a total of three further heat consumption circuits 30.1, 30.2, 30.3 being provided, each having corresponding second heat exchangers 32.1, 32.2, 32.3 within the heat storage unit 24. Identical components have the same reference and are not explained again.

A circulating pump 18, which can be controlled with regard to its power, with downstream non-return valve 54 is connected in the feed V1 of the first carrier medium circuit 22. Furthermore, a thermostat 56 is provided, which measures the temperature in the feed V1, in the return R1 of the first carrier medium circuit 22 and the temperature of the storage medium within the heat storage unit 24, and in doing so adjusts the power of the circulating pump 18 depending on the measured temperature. The thermostat 56 also monitors the maximum permissible temperature.

Furthermore, an expansion vessel 28 with upstream overpressure valve 60 is connected in the return R1 of the first carrier medium circuit 22.

A first second heat exchanger 32.1 of a first further heat consumption circuit 30.1, which is used for room heating for example, is provided in the top right-hand region in the interior of the heat storage unit 24. Below this is arranged a second heat exchanger 32.2 of a second further heat consumption circuit 30.2 (coolant circuit) which is associated with a heat pump 40.

Finally, a third second heat exchanger 32.3 is provided below this, which leads to a third further heat consumption circuit 30.3, which is used for the provision of hot water for example. The feeds and returns of the three further heat consumption circuits are specified by V21, V22, V23 and R21, R22 and R23 respectively. A further expansion vessel 72 is connected to the heat storage unit 24.

The feed V22 of the second further heat consumption circuit 30.2 is fed within the heat pump 40 to a compressor 62, a bypass valve 64 being connected between input and output of the compressor 62. In the further course of the second heat consumption circuit 30.2, this is fed to a steam generation unit 42, the temperature of the second carrier medium (coolant) of the second heat consumption circuit 30.2 being transferred via a third heat exchanger 66 to be steam pressure medium of the steam generation unit 42. A steam circuit 44 having a feed V4 and a return R4 is connected to the steam generation unit. The second carrier medium of the further second heat consumption circuit 30.2 is fed back to the heat exchanger 32.2 via the return R2. An expansion valve is arranged in the return R22 of the second further heat consumption circuit 30.2.

The feed V4 of the steam circuit 44 is fed to a steam turbine 46 and the resulting condensate is subsequently routed to a condensate storage unit 68.

A pump 70 in the return R4 of the steam circuit 44 feeds the condensate back into the steam generation unit 42.

The steam turbine 46 drives a generator 48, which feeds the generated electrical energy into a supply network.

Alternatively (as shown dotted in FIG. 2) or additionally, the steam turbine 46 can drive a nitrogen liquefaction unit 50 which extracts and liquefies nitrogen from the ambient air. The liquid nitrogen is subsequently stored in a nitrogen storage unit 52 in such a way that it can be drawn off. The liquid nitrogen can be used to drive nitrogen motors, for example, nitrogen motors of this kind being very environmentally compatible as no gases which are harmful to the environment are produced.

The steam turbine 46 is designed so that it can optionally be operated with the steam of the steam circuit 44 or with nitrogen. For this purpose, the steam turbine 46 is designed to be switchable with regard to the choice of operating medium. In FIG. 2, the steam turbine 46 is connected to the nitrogen storage unit 52 via an evaporator 76. Control components which control the changeover process are not shown in FIG. 2. At night, that is to say when the photovoltaic elements 12 are not active, or when no heat is being taken off elsewhere, the switchable steam turbine 46 enables electricity to be produced by the generator 48 and fed into the supply network.

The exemplary embodiment shown shows three examples of further consumption circuits 30.1, 30.2, 30.3 which can be connected to the heat storage unit 24. Further heat consumption circuits for other purposes can also be arranged without any problems.

The photovoltaic system 10 shown exhibits a considerably better efficiency compared with known photovoltaic systems. As well as the longer possible operating period of the photovoltaic system as such (exceeding the maximum temperature for the failure of the inverter is avoided), the process heat generated is used for further heat consumption circuits.

1. A photovoltaic system comprising:
planar photovoltaic elements, which when subjected to solar irradiation from above generate electrical energy which is fed into a power supply network and/or is supplied to an electricity storage unit;
a cooling unit, located under each photovoltaic element, that communicates with a first heat pump via a heat pump circuit, wherein the cooling unit feeds a process heat generated during the operation of the photovoltaic element to the first heat pump;
the first heat pump communicates with a first carrier medium circuit containing a first carrier medium;
a heat storage unit containing a heat storage medium that is arranged in the first carrier medium circuit, wherein the thermal energy of the first carrier medium is transferred to the heat storage medium within the heat storage unit;
at least one further heat consumption circuit containing a second carrier medium that communicates with the heat storage unit and said heat consumption circuit being fed to a heat pump, wherein the thermal energy of the heat storage medium is transferred to the second carrier medium of the further heat consumption circuit as required, and
a steam generation unit communicating with a steam circuit that is connected to the heat pump, a steam turbine being arranged in the steam circuit, wherein said steam turbine drives a generator for generating electricity and a nitrogen liquefaction unit which liquefies the nitrogen in the ambient air, and a nitrogen storage unit is provided in which the liquid nitrogen produced is stored in such a way that it can be drawn off, and said steam turbine can be switched in such a way that it is driven by the steam of the steam circuit or by nitrogen drawn from the nitrogen storage unit which is fed via an evaporator.

2. The photovoltaic system as claimed in claim 1, wherein an insulating layer is arranged below the cooling unit.

3. The photovoltaic system as claimed in claim 1, wherein the first carrier medium circuit has a first heat exchanger within the heat storage unit.

4. The photovoltaic system as claimed in claim 1, wherein the further heat consumption circuit has a second heat exchanger within the heat storage unit.

5. The photovoltaic system as claimed in claim 1, wherein a first circulating pump is located within the first carrier circuit.

6. The photovoltaic system as claimed in claim 1, wherein the further heat consumption circuit is used within a room heating system.

7. The photovoltaic system as claimed in claim 1, wherein the further heat consumption circuit is used within a system for the provision of hot water.

8-12. (canceled)
